(19) United States
(12) Patent Application Publication
(10) Pub. No.: US 2016/0183399 A1
(43) Pub. Date: Jun. 23, 2016

(54) DISPLAY DEVICE INCLUDING CURVED DISPLAY PANEL

(71) Applicant: Samsung Display Co., Ltd., Yongin-City (KR)

(72) Inventors: Cheolse LEE, Daegu (KR); Gyusu LEE, Asan-si (KR)

(21) Appl. No.: 14/732,895

(22) Filed: Jun. 8, 2015

(30) Foreign Application Priority Data
Dec. 23, 2014 (KR) 10-2014-0187184

(51) Int. Cl. H05K 7/02

(52) U.S. Cl. CPC H05K 7/02

(57) ABSTRACT

A display device includes: a display panel curved in at least a direction thereof; an intermediate frame including a first support portion supporting a rear edge portion of the display panel and having a predetermined curvature; an upper frame including a first bezel portion covering a front edge portion of the display panel and having a predetermined curvature; and an upper spacer disposed between the display panel and the first bezel portion.

This application claims priority to Korean Patent Application No. 10-2014-0187184, filed on Dec. 23, 2014, and all the benefits accruing therefrom under 35 U.S.C. §119, the contents of which in their entirety are herein incorporated by reference.

### BACKGROUND

1. Field

The invention relates to a display device, and more particularly, to a display device including an accommodating frame supporting a display panel to allow the display panel to have a predetermined curvature.

2. Description of the Related Art

Display devices are classified into liquid crystal display (“LCD”) devices, organic light emitting diode (“OLED”) display devices, plasma display panel (“PDP”) devices, electrophoretic display devices, and the like, based on a light emitting scheme thereof.

With an increase in an overall size of a display screen of a display device, a difference in viewing angle may occur between cases in which viewers are positioned at a center of the display screen and at a side (or end) of the display screen. In other words, when viewers observe an image displayed on a display screen of a relatively large display device from a position corresponding to a center of the display device, the image observed from the center of the display screen may be clearly perceived. In contrast, when viewers observe an image displayed on a display screen of a relatively large display device from a position corresponding to a side or end of the display device, the image observed from the side or end of the display screen may not be clearly perceived.

In order to compensate for such a difference in viewing angle, a curved display device having opposing ends disposed closer to a viewer than a center there to form a concave shape has been developed. Such curved display devices are classified into types including a landscape-type display device having a (horizontal) length greater than a (vertical) width thereof and curved in a length direction thereof, and a portrait-type display device having a (horizontal) length less than a (vertical) width thereof and curved in a width direction thereof.

### SUMMARY

A curved display device is manufactured in a manner in which a display panel of an initial flat shape is coupled to an accommodating frame manufactured having a curved shape. In this instance, due to a spring-back phenomenon, the display panel deformed by the accommodating frame desires to return to the initial flat shape thereof and, a shear stress occurs in the display panel. In particular, a shear stress occurring in a corner portion of the display panel deformed by the accommodating frame is greater than that occurring in a central portion of the display panel deformed by the accommodating frame, and thus, an issue of light leakage at the corner portion of the display panel arises. Therefore, an improved curved display device including a display panel therein is desired in which a shear stress of the display panel is minimized and light leakage thereof is reduced or effectively prevented.

One or more exemplary embodiment of the invention is directed to a display device capable of alleviating a shear stress occurring in a corner portion of a display panel of the display device in order to address a light leakage issue therein.

According to an exemplary embodiment of the invention, a display device includes: a display panel curved in at least a direction thereof; an intermediate frame disposed below the curved display panel, the intermediate frame including a first support portion overlapping a rear edge portion of the curved display panel and having a predetermined curvature; an upper frame disposed above the curved display panel, the upper frame including a first bezel portion covering a front edge portion of the curved display panel and having a predetermined curvature; and an upper spacer disposed between the display panel and the first bezel portion covering the front edge portion of the curved display panel.

The upper spacer may include a first upper spacer disposed at a corner portion of the curved display panel.

The upper spacer may further include a second upper spacer disposed at a non-corner portion of the curved display panel.

The display device may further include a lower spacer disposed between the display panel and the first support portion overlapping the rear edge portion of the curved display panel.

The lower spacer may be disposed non-overlapping with the upper spacer in a top plan view of the curved display panel.

In the display panel, an overall thickness of the curved display panel may be less than a distance between the first bezel portion covering the front edge portion of the curved display panel and the first support portion overlapping the rear edge portion of the curved display panel.

The first bezel portion covering the front edge portion of the curved display panel may be spaced apart from the first support portion by a distance of greater than or equal to about 0.5 millimeter (mm) and less than or equal to about 5.0 mm

The upper spacer may be attached to the first bezel portion covering the front edge portion of the curved display panel.

The lower spacer may be attached to the first support portion overlapping the rear edge portion of the curved display panel.

The first support portion overlapping the rear edge portion of the curved display panel and the first bezel portion covering the front edge portion of the curved display panel may be disposed to overlap one another in a top plan view of the curved display panel.

The predetermined curvatures of the first support portion portion overlapping the rear edge portion of the curved display panel and the first bezel portion covering the front edge portion of the curved display panel may be the same as one another.

The curved display panel may have a long side and a short side, and a length of the first upper spacer may be greater than or equal to about 1% of and less than or equal to about 10% of the long side of the curved display panel.

The curved display panel may have a long side and a short side, and a length of the second upper spacer may be equal to about 1% of and less than or equal to about 75% of the long side of the curved display panel.

The curved display panel may have a long side and a short side, and a length of the lower spacer may be greater than or equal to about 1% of and less than or equal to about 25% of the long side of the curved display panel.

A width of the upper spacer may be less than a width of the first bezel portion, the widths taken perpendicular to respective lengths thereof.

A width of the lower spacer may be less than a width of the first support portion, the widths taken perpendicular to respective lengths thereof.

A curvature of the curved display panel may be greater than a curvature at a non-corner portion thereof.

A curvature of the display panel may increase from the non-corner portion thereof to the corner portion thereof.

The curved display panel may include a display area in which an image is displayed and a non-display area in which an image is not displayed. The first support portion overlapping the rear edge portion of the curved display panel and the first bezel portion covering the front edge portion of the curved display panel may each be in the non-display area of the curved display panel.

The foregoing is illustrative only and is not intended to be in any way limiting.

In addition to the illustrative embodiments, and features described above, further embodiments, and features will become apparent by reference to the drawings and the following detailed description.

### BRIEF DESCRIPTION OF THE DRAWINGS

The above and other features of the invention will be more clearly understood from the following detailed description taken in conjunction with the accompanying drawings, in which:

FIG. 1 is a perspective view illustrating an exemplary embodiment of a display device according to the invention;

FIG. 2 is an exploded perspective view illustrating an exemplary embodiment of a display device according to the invention;

FIG. 3 is a cross-sectional view taken along line I-I of FIG. 2;

FIG. 4 is a cross-sectional view taken along line II-II of FIG. 2; and

FIG. 5 is a top plan view illustrating an exemplary embodiment of spacers in a display device according to the invention.

### DETAILED DESCRIPTION

Advantages and features of the invention and methods for achieving them will be made clear from exemplary embodiments described below in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. The invention is merely defined by the scope of the claims. Therefore, well-known constituent elements, operations and techniques are not described in detail in the exemplary embodiments in order to prevent the invention from being obscurely interpreted. Like reference numerals refer to like elements throughout the specification.

Throughout the specification, when an element is referred to as being “connected” to another element, the element is “directly connected” to the other element, or “electrically connected” to the other element with one or more intervening elements interposed therebetween.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises,” “comprising,” “includes” and/or “including,” when used in this specification, specify the presence of stated features, integers, steps, operations, elements, and/or components, but do not preclude the presence or addition of one or more other features, integers, steps, operations, elements, components, and/or groups thereof.

It will be understood that, although the terms “first,” “second,” “third,” and the like may be used herein to describe various elements, these elements should not be limited by these terms. These terms are only used to distinguish one element from another element. Thus, “a first element” discussed below could be termed “a second element” or “a third element,” and “a second element” and “a third element” can be termed likewise without departing from the teachings herein.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within±30%, 20%, 10%, 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein. All terminologies used herein are merely used to describe embodiments of the inventive concept and may be modified according to the relevant art and the intention of an applicant. Therefore, the terms used herein should be interpreted as having a meaning that is consistent with their meanings in the context of the present disclosure, and is not intended to limit the invention.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, exemplary embodiments of a display device according to the invention are explained with respect to a liquid crystal display (“LCD”) device. However, the display device is not limited thereto, and features of the invention may also be applied to an organic light emitting diode (“OLED”) display device.

In addition, exemplary embodiments of the display device according to the invention are explained with respect to an edge-type backlight unit. However, the display device is not limited thereto, and may also include a direct-type backlight unit or a corner-type backlight unit.

Further, exemplary embodiments of the display device according to the invention are explained with respect to a landscape-type display device, having a length greater than a width thereof and curved in a length direction thereof. However, the type of the display device is not limited thereto and may include a portrait-type display device.

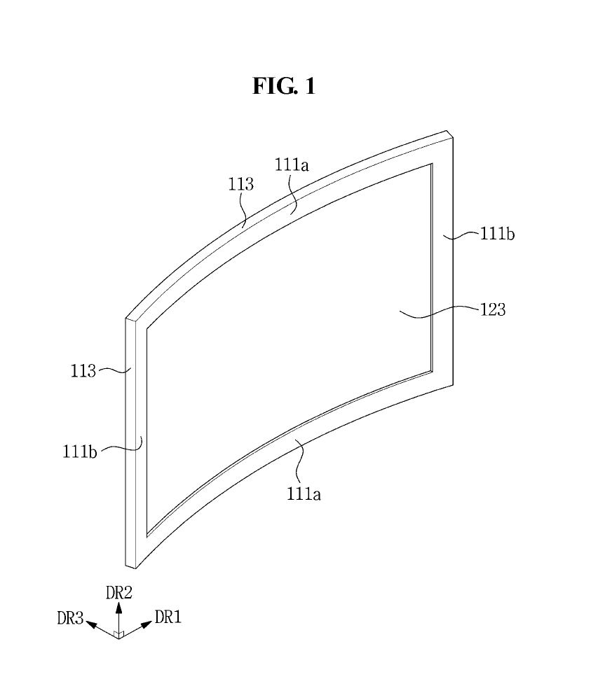

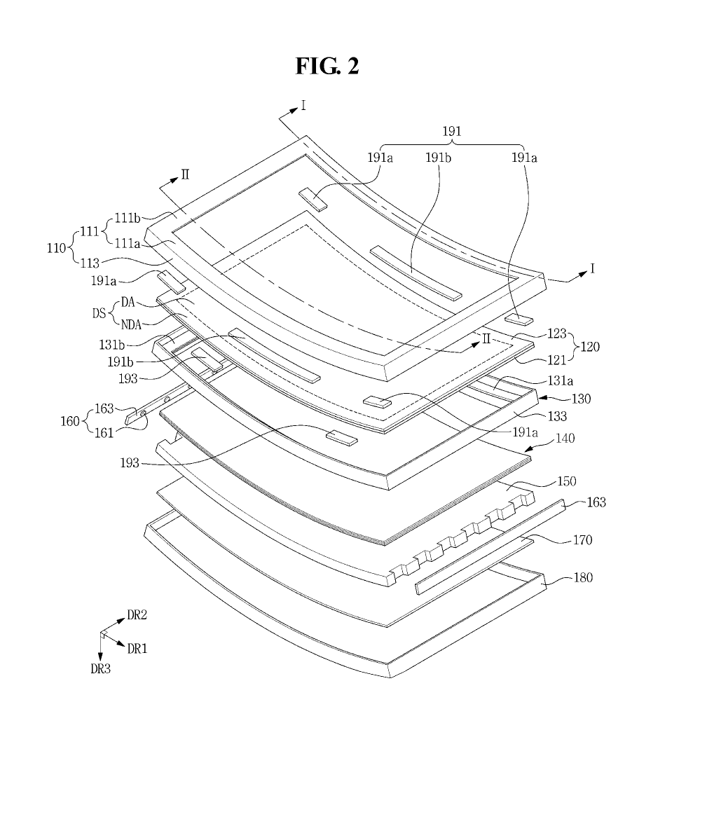

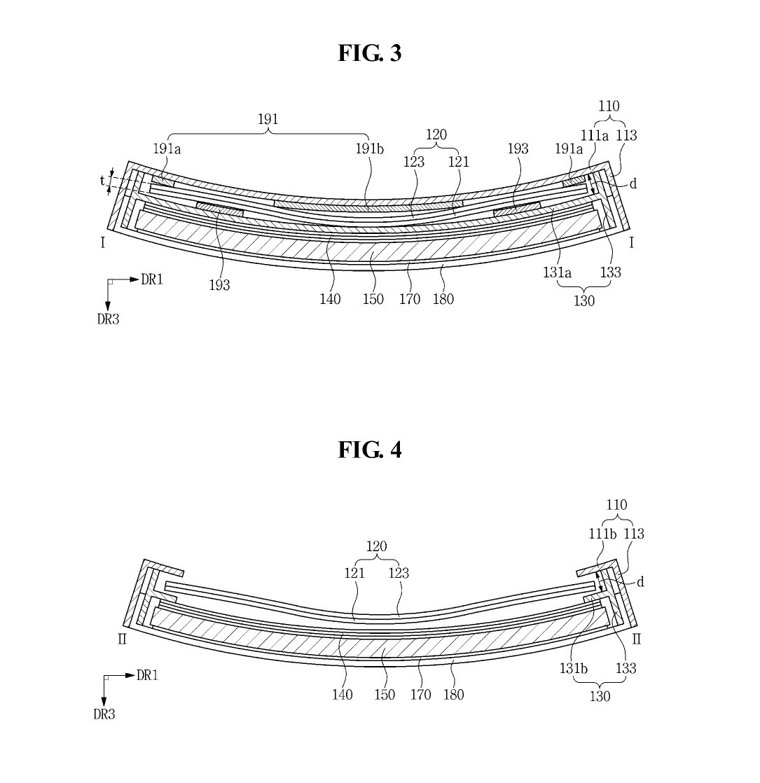

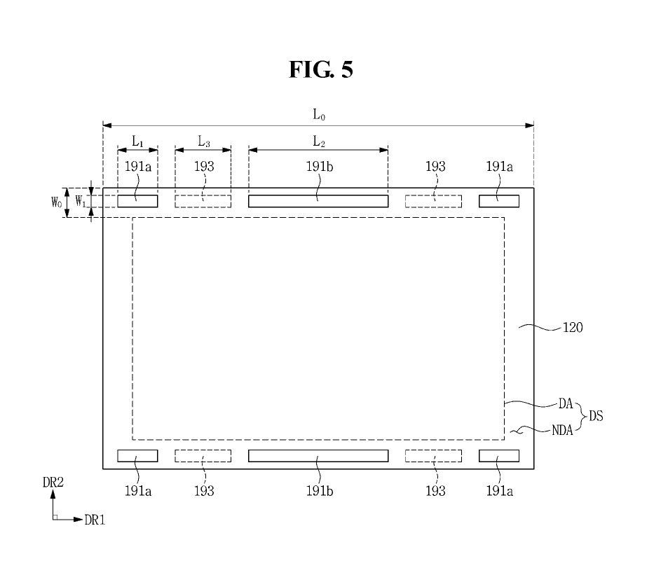

FIG. 1 is a perspective view illustrating an exemplary embodiment of a display device according to the invention; FIG. 2 is an exploded perspective view illustrating an exemplary embodiment of a display device according to the invention; FIG. 3 is a cross-sectional view taken along line I-I of FIG. 2; and FIG. 4 is a cross-sectional view taken along line II-II of FIG. 2.

Referring to FIGS. 1 and 2, a display device may include an upper frame 110, a display panel 120, an intermediate frame 130, an optical sheet 140, a light guide plate 150, a light source unit 160, a reflective sheet 170 and a lower frame 180. Hereinafter, the intermediate frame 130, the optical sheet 140, the light guide plate 150, the light source unit 160, the reflective sheet 170, the lower frame 180, and the like, will be collectively referred to as a backlight unit. The above-described components of the display device may have a concave curved shape corresponding to a curved shape of the overall display device.

An accommodating frame, such as the upper frame 110, the intermediate frame 130 and the lower frame 180, may be manufactured to have a predetermined curvature. The display panel 120 of the display device may have an initial curved shape, prior to being coupled to the accommodating frame of the display device, or alternatively, may have a curved shape through being coupled to the accommodating frame of the display device.

That is, where the display panel 120 is a flexible display panel, an initially flat display panel 120 may be coupled to the accommodating frame, such that the display panel 120 has a curved shape through being coupled to the accommodating frame of the display device. On the other hand, where the display panel 120 is initially a rigid-type (e.g., flat or non-flexible) display panel, the display panel 120 may initially have a predetermined curvature prior to being inserted into the accommodating frame of the display device.

In one exemplary embodiment, the display panel 120 is manufactured in an initially flat shape, and is thereafter coupled to the accommodating frame having a predetermined curvature, thereby deforming the initially flat display panel 120 to have the predetermined curvature. The accommodating frame may have a radius of curvature of greater than or equal to about 1000 millimeters (mm) and less than or equal to about 5000 mm

The display panel 120 may have a rectangular shape when viewed in a plane such as a top (e.g., viewing side) plan view. Hereinafter, for ease of description, a length direction, a width direction and a thickness direction of the display panel 120 are referred to as a horizontal direction DR1, a vertical direction DR2 and a normal direction DR3, respectively.

The display panel 120, which is provided in a quadrangular planar form and displays an image using light provided from the backlight unit, may be a flexible display panel configured to be curved in at least a direction thereof. The display panel 120 may be deformed from a flat or planar state, along one or more of a relatively long side of the display panel 120, such that the deformed display panel 120 is curved in a concave manner to have a predetermined curvature. Alternatively or additionally, the display panel 120 may be deformed from a flat or planar state, along one or more of a relatively short side of the display panel 120, such that the deformed display panel 12 may be further curved in a concave manner to have a predetermined curvature.

The display panel 120 may provide a display surface DS having a concave curved shape. The display surface DS may include a display area DA in which a still image and/or a moving image is displayed and a non-display area NDA provided along an edge of the display area DA.

The display panel 120 may include a first substrate 121, a second substrate 123 opposing the first substrate 121, and a liquid crystal layer (not illustrated) between the first and second substrates 121 and 123.

In the first substrate 121, a plurality of pixel electrodes may be disposed in a form of a matrix, a thin film transistor (“TFT”) applying a driving voltage may be connected to each pixel electrode, and various types of signal lines for driving the pixel electrode and the TFT may be connected to the pixel electrode and the TFT.

The second substrate 123 may be disposed to oppose the first substrate 121. In the second substrate 123, a common electrode including or formed of a transparent conductive material, and a color filter, may be disposed. The color filter may include red, green, and blue filters, by way of example, but the invention is not limited thereto.

The liquid crystal layer (not illustrated) may be interposed between the first and second substrates 121 and 123, and liquid crystals therein may be rearranged by an electric field formed between the common electrode and one or more of the pixel electrodes. In detail, the rearranged liquid crystals in the liquid crystal layer may adjust a level of transmissivity of light emitted from the backlight unit, and the light having the adjusted level of transmissivity may pass through the color filter to thereby display an image outwardly at the viewing side of the display device.

In addition, although not illustrated in FIG. 1, the display device may include a lower polarizing plate and an upper polarizing plate may further be disposed on a lower surface of the first substrate 121 and an upper surface of the second substrate 123, respectively. The upper polarizing plate and the lower polarizing plate may each have an area corresponding to an area of the display panel 120. The upper polarizing plate may transmit a predetermined component of polarized light from among externally supplied light thereto, and may absorb or block the remainder of the externally supplied light thereto. The lower polarizing plate may transmit a predetermined component of polarized light from among the light emitted from the backlight unit thereto, and may absorb or block the remainder of the light emitted from the backlight unit thereto.

A drive circuit board (not illustrated) configured to drive the display panel 120 may be disposed on a side of the display panel 120. The drive circuit board may provide various types of control signals and/or power signals used in a driving state of the display panel 120.

In the upper frame 110, an open window through which the display area DA of the display panel 120 is exposed outwardly may be defined. The upper frame 110 may be disposed to cover a front edge portion and a side surface of the display panel 120.

The upper frame 110 may include a bezel portion 111 covering (e.g., overlapping) the front edge portion of the display panel 120, that is, the non-display area NDA, and a side wall portion 113 which may be continuous bent downwardly from the bezel portion 111 to cover the side surface of the display panel 120.

The bezel portion 111 may fix the front edge portion of the display panel 120 to thereby reduce or effectively prevent movement of the display panel 120 from within the backlight unit. The bezel portion 111 may include a first bezel portion 111a which is curved to be concave in the horizontal direction DR1 and a second bezel portion 111b extending from the first bezel portion 111a in the vertical direction DR2.

The side wall portion 113 may be fixed to the intermediate frame 130 and the lower frame 180 through hook coupling and/or screw coupling, but the invention is not limited thereto.

The upper frame 110 may be collectively formed as a single, unitary frame or may be formed by a plurality of separately provided portions which are subsequently assembled, as necessary. The upper frame 110 may include or be formed of a metal material having rigidity such as stainless steel and/or a material having excellent heat dissipation properties such as aluminum (Al) or an Al alloy. In an exemplary embodiment of manufacturing a display device, the upper frame 110 may be formed through a press die process, and the like, to allow the first bezel portion 111a to have a predetermined curvature.

The intermediate frame 130 may overlap the display panel 120 to support the display panel 120, and may accommodate the optical sheet 140, the light guide plate 150, the light source unit 160, the reflective sheet 170, and the like, therein.

The intermediate frame 130 may have a polygonal frame shape in which an opening is defined therein. In an exemplary embodiment, for example, the intermediate frame 130 may have a quadrangular frame shape in which an opening is defined therein. The intermediate frame 130 may be collectively formed as a single, unitary frame or may be formed by a plurality of separately provided portions which are subsequently assembled, as necessary.

The intermediate frame 130 may include a support portion 131a and 131b and a side wall portion 133. The support portion 131a and 131b overlaps the display panel 120 to support a rear edge portion of the display panel 120, that is, the non-display area NDA, and the side wall portion 133 extends from the support portion 131a and 131b in the normal direction DR3.

The support portion 131a and 131b may include a first support portion 131a which is curved to be concave in the horizontal direction DR1 and a second support portion 131b extending from the first support portion 131a in the vertical direction DR2.

A distance between the bezel portion 111 of the upper frame 110 and the support portion 131a and 131b of the intermediate frame 130 may be adjusted by the side wall portion 133 of the intermediate frame 130.

The intermediate frame 130 may include or be formed of a flexible material such as a plastic. In an exemplary embodiment of manufacturing a display device, the intermediate frame 130 may be formed through an injection molding process, or the like. The intermediate frame 130 may be formed through the injection molding process, or the like, to allow the first support portion 131a to have a predetermined curvature.

The bezel portion 111 of the upper frame 110 and the support portion 131a and 131b of the intermediate frame 130 may be disposed to overlap one another in the top plan view. In an exemplary embodiment, the first bezel portion 111a and the first support portion 131a may be disposed to overlap one another in the top plan view. The first bezel portion 111a and the first support portion 131a may be curved to have the same curvature as one another.

In a cross-sectional direction taken along the normal direction DR3, an upper spacer 191 may be disposed between the first bezel portion 111a and the display panel 120, and a lower spacer 193 may be disposed between the display panel 120 and the first support portion 131a. The upper spacer 191 may include a first upper spacer 191a disposed at a corner portion of the display panel 120 and a second upper spacer 191b disposed at a central (e.g., non-corner) portion of the display panel 120.

Details pertaining to the configuration of the upper spacer 191 and the lower spacer 193 will be provided later.

The optical sheet 140 may be disposed on the light guide plate 150, and may serve to diffuse or collect light transmitted from the light guide plate 150. The optical sheet 140 may be curved to be concave in the horizontal direction DR1. The optical sheet 140 member may collectively include a diffusion sheet, a prism sheet and a protective sheet. The diffusion sheet, the prism sheet and the protective sheet may be sequentially stacked on the light guide plate 150.

The prism sheet may collect light guided by the light guide plate 150, the diffusion sheet may disperse light collected by the prism sheet, and the protective sheet may protect the prism sheet. Light having passed through the protective sheet may be supplied to the display panel 120.

The light guide plate 150 may uniformly supply light generated and provided from the light source unit 160 to the display panel 120. In an exemplary embodiment of manufacturing a display device, the light guide plate 150 may be manufactured initially in a flat shape, and may be curved to be concave in the horizontal direction DR1 through being coupled to the accommodating frame of the display device. The light guide plate 150 may include or be formed of a flexible material such that the light guide plate 150 may be manufactured to have a predetermined curvature.

The light guide plate 150 may have a quadrangular planar form, however, is not limited thereto. According to an exemplary embodiment, where an LED chip is used as a light source of the display device, the light guide plate 150 may have various forms such as including a predetermined groove and/or a protrusion defined therein based on a position of the light source.

For ease of description, the light guide plate 150 is described as a plate having a relatively large thickness, however, the light guide plate 150 may be provided in a sheet or film shape having a smaller thickness as compared to that of the plate shape, to achieve an overall slimness of the display device. In other words, the light guide plate 150 which is configured to guide light generated by the light source is to be understood as having a shape of not only a plate but also of a film.

The light guide plate 150 may include or be formed of a light-transmissive material, for example, an acrylic resin such as polymethyl methacrylate (“PMMA”) or polycarbonate (“PC”) in order to guide light efficiently.

The light source unit 160 may include a light source 161, and a circuit board 163 on which the light source 161 is disposed.

The light source 161 may be disposed on an edge of the light guide plate 150 or on (e.g., overlapping in the top plan view) a light incident surface of the light guide plate 150. In other words, the light source 161 may emit light toward the edge of the light guide plate 150 or may emit light toward the light incident surface such as a lower surface of the light guide plate 150. The light source 161 may include a light emitting diode (“LED”) chip (not illustrated) and a package (not illustrated) accommodating the LED chip therein. In an exemplary embodiment, for example, the LED chip (not illustrated) may be a gallium nitride (GaN)-based LED chip configured to emit blue light.

The number of light sources 161 within the light source unit 160 may vary based on a size, luminance uniformity, and the like, of the display panel 120. The circuit board 163 may be a printed circuit board (“PCB”) or a metal printed circuit board (“MPCB”).

Although not illustrated in FIG. 2, a wavelength converting unit (not illustrated) may be disposed between the light guide plate 150 and the light source unit 160. The wavelength converting unit (not illustrated) may include a material converting a wavelength of light incident thereto. In an exemplary embodiment, for example, the wavelength converting unit may convert a wavelength of blue light emitted from a blue LED light source to obtain white light therefrom.

In addition, although not illustrated in FIG. 2, a heat dissipation member (not illustrated) may be disposed between the light source unit 160 and the lower frame 180. The heat dissipation member (not illustrated) may be configured to dissipate heat generated in the light source unit 160 to outside the backlight unit and/or the display device. Where the light source unit 160 is disposed at a side surface of the lower frame 180 in a form of a bar or a line, the heat dissipation member may also be disposed as a metal frame having a bar or line form. As such, the heat dissipation member may have various shapes based on the form of the light source unit 160.

The reflective sheet 170 may be disposed between the light guide plate 150 and the lower frame 180. The reflective sheet 170 may reflect light emitted downwardly from the light guide plate 150 toward the display panel 120, thereby enhancing light efficiency of the display device. The reflective sheet 170 may be curved to be concave in the horizontal direction DR1.

The reflective sheet 170 may include or be formed of, for example, polyethylene terephthalate (“PET”) to have reflectivity. A surface of the reflective sheet 170 may be coated with a diffusion layer containing, for example, titanium dioxide (TiO₂). In addition, the reflective sheet 170 may include or be formed of a material containing a metal, such as silver (Ag).

The lower frame 180 may serve to maintain a framework of the display device, and may protect various components accommodated therein. The lower frame 180 may be curved to be concave in the horizontal direction DR1. The lower frame 180 may include or be formed of a metal material having rigidity such as stainless steel, or a material having excellent heat dissipation properties such as Al or an Al alloy. In an exemplary embodiment of manufacturing a display device, the lower frame 180 may be formed through a press die process, and the like, to have a predetermined curvature.

Referring to FIGS. 3 and 4, the display panel 120 may have an overall or total thickness “t” less than a distance “d” between the first bezel portion 111a and the first support portion 131a. The distance “d” may also be defined between the second bezel portion 111b and the second support portion 131b. In an exemplary embodiment, for example, the distance “d” between the first bezel portion 111a and the first support portion 131a may be greater than or equal to about 0.5 mm and less than or equal to about 5.0 mm.

Where the distance “d” between the first bezel portion 111a and the first support portion 131a is the same as the overall or total thickness “t” of the display panel 120, the display panel 120 may be curved in a concave manner to have the same curvature as that of the first bezel portion 111a or the first support portion 131a.

However, as in the exemplary embodiment of the invention, where the distance “d” between the first bezel portion 111a and the first support portion 131a is greater than the overall or total thickness “t” of the display panel 120, the display panel 120 may be curved to have a curvature greater than that of the first bezel portion 111a or the first support portion 131a.

That is, since the display panel 120 may be curved to have a curvature greater than that of the first bezel portion 111a or the first support portion 131a, a shear stress applied to the display panel 120 may be alleviated, and thus, light leakage occurring at the corner portion of the display panel 120 may be reduced. Such a shear stress may refer to a force generated due to a spring-back phenomenon in which the display panel 120 desires to return to an initial flat state thereof from a deformed or curved state thereof.

The distance “d” between the first bezel portion 111a and the first support portion 131a may be adjusted by the side wall portion 133 of the intermediate frame 130.

The lower spacer 193 may be disposed not to overlap the first and second upper spacers 191a and 191b.

The upper spacer 191 and the lower spacer 193 may include or be formed of a material having elasticity such as rubber, and may be configured to block light such as having a black color.

Referring to FIG. 4, the upper spacer 191 may be accommodated in and/or fill an empty space between the first bezel portion 111a and the display panel 120, and the lower spacer 193 may be accommodated in and/or fill an empty space between the first support portion 131a and the display panel 120.

In addition, in the cross-sectional thickness direction (e.g., DR3) the upper spacer 191 and the lower spacer 193 may be disposed upwardly and downwardly of the display panel 120, respectively, to adjust a deformed state of the display panel 120 to have a predetermined curvature.

In particular, the first upper spacer 191a may be disposed at the corner portion of the display panel 120 to alleviate a shear stress therein, thereby reducing light leakage occurring at the corner portion of the display panel 120.

Moreover, the upper and lower spacers 191 and 193 may reduce or effectively prevent damage to the display panel 120 due to the upper and intermediate frames 110 and 130, may discharge electrostatic charges accumulated in the display panel 120 externally, and/or may block light leakage between the upper frame 110 and the display panel 120.

The upper spacer 191 may be attached or fixed to a lower surface of the first bezel portion 111a, and the lower spacer 193 may be attached or fixed to an upper surface of the first support portion 131a. In an exemplary embodiment, the upper spacer 191 may be attached or fixed to a front surface of the display panel 120, and the lower spacer 193 may be attached or fixed to a rear surface of the display panel 120.

The upper and lower spacers 191 and 193 may be fixed to the upper frame 110, the intermediate frame 130, the display panel 120, or the like, such as by using an adhesive member. The adhesive member may include a double-sided tape (not illustrated).

FIG. 5 is a top plan view illustrating an exemplary embodiment of attached positions of spacers according to the invention. FIG. 5 is a top plan view illustrating a relative size of the upper and lower spacers 191 and 193 based on the size of the display panel 120.

Among the spacers, it will be assumed that an overall or total length of the display panel 120 in the horizontal direction DR1 is denoted by L₀, an overall or total length of a first upper spacer 191a in the horizontal direction DR1 is denoted by L₁, an overall or total length of a second upper spacer 191b in the horizontal direction DR1 is denoted by L₂, an overall or total length of a lower spacer 193 in the horizontal direction DR1 is denoted by L₃, and an overall or total width of each of the upper and lower spacers 191 and 193 in the vertical direction DR2 is denoted by W₁. A sum of the lengths of the spacers in the horizontal direction DR1 may be equal to or less than the overall or total length L₀ of the display panel 120.

The display surface DS may include the display area DA in which a still image or a moving image is displayed, and the non-display area NDA provided along the edge of the display area DA. It will be assumed that a width of a portion of the non-display area NDA at one side of the display area DA is denoted by W₀.

Referring to FIG. 5, the upper and lower spacers 191 and 193 may be disposed in the non-display area NDA of the display panel 120. Within the non-display area NDA, the first upper spacer 191a may be disposed at the corner portion of the display panel 120, and the second upper spacer 191b may be disposed at the central (e.g., non-corner) portion of the display panel 120.

The length L₁ of the first upper spacer 191a may have a value greater than or equal to about 1% of and less than or equal to about 10% of the length L₀ of the display panel 120.

The length L₂ of the second upper spacer 191b may have a value greater than or equal to about 1% of and less than or equal to about 75% of the length L₀ of the display panel 120.

The length L₃ of the lower spacer 193 may have a value greater than or equal to about 1% of and less than or equal to about 25% of the length L₀ of the display panel 120.

In addition, the non-display area NDA of the display panel 120 may be an area covered by the bezel portion 111 of the upper frame 110 or supported by the support portion 131a and 131b of the intermediate frame 130.

The width W₁ of the upper and lower spacers 191 and 193 may be less than a width of the first bezel portion 111a of the upper frame 110, or may be less than a width of the first support portion 131a of the intermediate frame 130. That is, the width W₁ of the upper and lower spacers 191 and 193 may be less than the width W₀ of the non-display area NDA at the one side of the display area DA.

In addition, the first upper spacer 191a may be disposed at the corner portion of the display panel 120 to alleviate a shear stress occurring therein, thereby reducing light leakage occurring at the corner portion of the display panel 120.

Referring to the cross-sectional thickness direction (e.g., DR3), the second upper spacer 191b and the lower spacer 193 may be disposed upwardly and downwardly of the display panel 120, respectively, and may adjust a deformed state of the display panel 120 to have a predetermined curvature.

The display panel 120 may have a greater curvature at the corner portion thereof than that at the central (e.g., non-corner) portion thereof. That is, the display panel 120 may have a curvature which increases from the central portion to the corner portion thereof.

As set forth above, according to one or more exemplary embodiment of the invention, the curved display device may increase the distance between the accommodating frames supporting the display panel to alleviate a shear stress occurring at the corner portion of the display panel, thereby reducing light leakage occurring therein.

By disposing the spacer between the display panel and the accommodating frame, the display panel may have a predetermined curvature, and a shear stress occurring at the corner portion of the display panel may be alleviated, thereby reducing light leakage occurring at the corner portion of the display panel.

From the foregoing, it will be appreciated that various embodiments in accordance with the disclosure have been described herein for purposes of illustration, and that various modifications may be made without departing from the scope and spirit of the invention. Accordingly, the various exemplary embodiments disclosed herein are not intended to be limiting of the true scope and spirit of the invention. Various features of the above described and other exemplary embodiments can be mixed and matched in any manner, to produce further exemplary embodiments consistent with the invention.

What is claimed is:

1. A display device comprising:
a display panel curved in at least a direction thereof;
an intermediate frame disposed below the curved display panel, including a first support portion overlapping a rear edge portion of the curved display panel and having a predetermined curvature;
an upper frame disposed above the curved display panel, including a first bezel portion covering a front edge portion of the curved display panel and having a predetermined curvature; and
an upper spacer disposed between the curved display panel and the first bezel portion covering the front edge portion of the curved display panel.

2. The display device of claim 1, wherein the upper spacer includes a first upper spacer at a corner portion of the curved display panel.

3. The display device of claim 2, wherein the upper spacer further includes a second upper spacer at a non-corner portion of the curved display panel.

4. The display device of claim 1, further comprising a lower spacer disposed between the curved display panel and the first support portion overlapping the rear edge portion of the curved display panel.

5. The display device of claim 4, wherein the lower spacer is disposed non-overlapping with the upper spacer in a top plan view of the curved display panel.

6. The display device of claim 1, wherein an overall thickness of the curved display panel is less than a distance between the first bezel portion covering the front edge portion of the curved display panel and the first support portion overlapping the rear edge portion of the curved display panel.

7. The display device of claim 1, wherein the first bezel portion covering the front edge portion of the curved display panel is spaced apart from the first support portion overlapping the rear edge portion of the curved display panel by a distance greater than or equal to about 0.5 millimeter and less than or equal to about 5.0 millimeters.

8. The display device of claim 1, wherein the upper spacer is attached to the first bezel portion covering the front edge portion of the curved display panel.

9. The display device of claim 4, wherein the lower spacer is attached to the first support portion overlapping the rear edge portion of the curved display panel.

10. The display device of claim 1, wherein the first support portion overlapping the rear edge portion of the curved display panel and the first bezel portion covering the front edge portion of the curved display panel are disposed overlapping one another in a top plan view of the curved display panel.

11. The display device of claim 1, wherein the predetermined curvatures of the first support portion portion overlapping the rear edge portion of the curved display panel and the first bezel portion covering the front edge portion of the curved display panel are the same as one another.

12. The display device of claim 2, wherein
the curved display panel has a long side and a short side, and
a length of the first upper spacer is greater than or equal to about 1% of and less than or equal to about 10% of the long side of the curved display panel.

13. The display device of claim 3, wherein
the curved display panel has a long side and a short side, and
a length of the second upper spacer is greater than or equal to about 1% of and less than or equal to about 75% of the long side of the curved display panel.

14. The display device of claim 4, wherein
the curved display panel has a long side and a short side, and
a length of the lower spacer has is greater than or equal to about 1% of and less than or equal to about 25% of the long side of the curved display panel.

15. The display device of claim 1, wherein a width of the upper spacer is less than a width of the first bezel portion, the widths taken perpendicular to respective lengths thereof.

16. The display device of claim 4, wherein a width of the lower spacer is less than a width of the first support portion, the widths taken perpendicular to respective lengths thereof.

17. The display device of claim 1, wherein a curvature of the curved display panel at a corner portion thereof is greater than a curvature of the curved display panel at a non-corner portion thereof.

18. The display device of claim 17, wherein a curvature of the curved display panel increases from the non-corner portion thereof to the corner portion thereof.

19. The display device of claim 5, wherein
the curved display panel includes a display area in which an image is displayed and a non-display area in which an image is not displayed, and
the first support portion overlapping the rear edge portion of the curved display panel and the first bezel portion covering the front edge portion of the curved display panel are in the non-display area of the curved display panel.
